(19) United States
(12) Patent Application Publication
(10) Pub. No.: US 2008/0068225 A1
(43) Pub. Date: Mar. 20, 2008

(54) HOLOGRAPHIC SYMBOLS ON SOFT KEYS OF ELECTRONIC EQUIPMENT AND METHOD

(76) Inventor: Per Wahlstrom, Malmo (SE)

Correspondence Address: WARREN A. SKLAR (SOER);RENNER, OTTO, BOISSELLE & SKLAR, LLP, 1621 EUCLID AVENUE, 19TH FLOOR, CLEVELAND, OH, 44115, US

(21) Appl. No.: 11/470,388

(22) Filed: Sep. 6, 2006

(51) Int. Cl. H03M 11/00

(52) U.S. Cl. 341/22

(57) ABSTRACT

Electronic equipment, e.g., mobile telephone, PDA, etc., has keys that may be pressed or otherwise operated to operate the equipment. A hologram associated with one or more of the keys provides respective distinguishable outputs to indicate functions expected to be carried out in response to operating the key. One or more light inputs from different respective directions selectively are provided the hologram to cause respective distinguishable outputs from the hologram. Light to the light paths may be provided by respective LEDs or other light output devices or light may be provided several light paths from a shared light output device via an optical switch.

A method for providing distinguishable optical outputs for electronic equipment includes providing respective light inputs from different respective directions to a hologram associated with an operable key to indicate the function to be carried out upon operating such key.

### TECHNICAL FIELD OF THE INVENTION

The present invention relates generally to the field of electronic equipment with at least one key, button, manually operable switch, etc. (collectively referred to below as “key”) that can be pressed or otherwise operated to cause a desired function or operation of the electronic equipment, and, more particularly, to changing graphics on a soft key button for electronic equipment depending on what application currently is being run on the electronic equipment. Additionally, the invention relates to use of holographic symbols on soft keys of electronic equipment to present a number of distinguishable indicia to indicate functions expected to be carried out by the electronic equipment in response to operating the key.

### DESCRIPTION OF RELATED ART

Modern electronic equipment include one or more keys to provide inputs to operate the electronic equipment. The electronic equipment may be, for example, but not limited to, mobile phones (also referred to as mobile telephones) and other communications devices, personal digital assistants (PDAs), hand-held computers, electronic games, GPS devices, etc. One or more keys may be selectively operated or activated by a user, e.g., by pressing, sliding, or some other operation or activation, to provide inputs to the electronic equipment. In response to the inputs the electronic equipment would carry out selected functions, activities, operations or the like (such terms being used interchangeably and essentially equivalently herein unless otherwise indicated by context).

The keys may be in various arrangements, such as a conventional touch tone telephone or push button telephone dialing keypad, a QWERTY typewriter keypad (or that of a language other than a typical English language keyboard), etc. The electronic equipment also may include a display for displaying menus, information, data, icons, pictures, videos, etc.; the display may be a touch sensitive display to provide inputs to the electronic equipment when touched at selected locations to cause the electronic equipment to carry out selected functions. Several examples of functions include scrolling through a series of menus, initiating a telephone call or receiving a telephone call, transmitting data or receiving data, carrying out an email function, a text messaging function or calendar function, selecting and/or initiating a given function, turning on or off the electronic equipment, etc. The electronic equipment also may have a navigation device to move a cursor on the display, to scroll through menus and/or icons shown on the display, and possibly also to select functions of the electronic equipment as are represented by such menus, icons, etc.

One or more keys of the electronic equipment may be soft keys. A soft key sometimes may be referred to as a multifunction key. Typically a soft key is located in proximity to, for example, directly adjacent, an area of the display at which one or more words or icons representing different respective functions may be shown to identify the function that would be carried out upon pressing the soft key while such word(s) and/or icon(s) are being shown. Exemplary words that may be show on the display proximate a soft key may be select, erase, play, back forward, up, down, increase, decrease, delete, etc. These are only several examples of such functions and it will be appreciated that other functions may be carried out upon operating a soft key.

Modern mobile phones also typically have a control module, for example, including a communications module and an operation control. The control module may carry out the various functions of the mobile phone, e.g., making and receiving telephone calls, showing icons, photographs, menus of functions, etc., on the display, carrying out various computer programs or the like, e.g., word processing, spread sheet, etc., programs, text messaging, playing music, showing photographs, playing videos, etc.

To provide the user inputs for electronic equipment, such as a mobile phone, e.g., to the control module thereof, one or more keys of the keyboard, also referred to as keypad, may be pressed, the navigation device may be operated and/or the touch sensitive screen of the display may be touched. In response to the inputs, the control module carries out functions of the electronic equipment and also coordinates the display operation to show appropriate information, e.g., menus, icons, pictures, etc.

The soft keys and the navigation device may be coordinated with images shown on the display. Showing images that identify the current function(s) to be carried out if a soft key were pressed uses area of the display. If that area were not needed to show soft key function(s), the area may be used to present other information, etc., to a user and may increase the versatility and/or functionality of the electronic equipment. Also, soft keys usually are located adjacent a display so the current function of the soft key, if it were pressed, easily can be understood due to the close placement of the soft key and the word(s) or icon shown in the nearby area of the display. However, such close placement requirement tends to restrict places where soft keys can be positioned in the electronic equipment and, thus, may limit variations and efficiencies in key board/keypad design.

Accordingly, there is a need to improve labeling for soft keys and the like for electronic equipment.

There also is a need to identify the functions of soft keys without consuming area or at least while reducing area of a display needed to identify those functions.

Further, there is a need to identify multiple functions of soft keys that are not adjacent a display, thus increasing freedom to change the layout of keyboards that include soft keys or other multifunction keys and/or increasing the number of soft key type of keys that may be used in electronic equipment.

There also is a need to reduce reliance on the display of electronic equipment to show soft key labels.

### SUMMARY OF THE INVENTION

Briefly, an aspect of the invention relates to changing images on one or more soft keys or the like of electronic equipment to represent respective operations that would occur in response to pressing or the like such soft key(s).

Another aspect relates to using holograms on one or more soft keys or the like of electronic equipment and selectively illuminating the holograms with incident light to create different respective indicia or images.

An aspect of the present invention relates to electronic equipment including a communications module, and an input module, and wherein the input module comprises at least one manually operable key and an optical device having a number of distinguishable indicia associated with said key and being selectable to display respective indicia based on a respective characteristic of illumination thereof.

According to another aspect, the respective characteristic of illumination is direction of illumination.

According to another aspect, the optical device is a hologram.

According to another aspect, the respective characteristic is wavelength of light.

According to another aspect, the communications module comprises a mobile phone.

According to another aspect, the communications module comprises a personal digital assistant.

According to another aspect, the optical device is adapted to provide images located at the optical device.

According to another aspect, the optical device is adapted to provide images spaced apart from the optical device.

According to another aspect, a number of light sources respectively provide visible light to the optical device from different locations.

According to another aspect, electronic apparatus is operable to control the communications module, the electronic apparatus and the input module being cooperatively related whereby the respective distinguishable indicia provided by the optical device are determined under control of the electronic apparatus.

According to another aspect, electronic equipment includes operational component to carry out functions (display, computation, calculation, listing of music, telephone communications) in response to an input from an operated key, and a key adapted to provide an input to the operational component, the key including a hologram adapted to provide respective distinguishable optical outputs (views, images, information) in response to the characteristics of incident light provided the hologram.

According to another aspect, a plurality of light paths along which light inputs are provided, respectively, to the hologram provide different respective distinguishable optical outputs.

According to another aspect, electronic equipment includes an activatable element operable to provide a discernible indication of being selectively activated, and a changeable display in the activatable element and adapted to provide at least two distinguishable optical outputs in response to respective optical inputs, such outputs indicative, respectively, of anticipated effect of activating the activatable element.

Another aspect relates to a method for providing distinguishable optical outputs for electronic equipment, comprising providing respective light inputs to a hologram associated with an operable key to indicate the function to be carried out upon operating such key.

According to another aspect, the method includes changing the characteristic of incident light on the hologram to change indicia shown by the hologram.

According to another aspect, the changing characteristic comprises changing the direction of incidence.

According to another aspect, the changing characteristic comprises changing the wavelength of light.

These and further features of the present invention will be apparent with reference to the following description and attached drawings. In the description and drawings, particular embodiments of the invention have been disclosed in detail as being indicative of some of the ways in which the principles of the invention may be employed, but it is understood that the invention is not limited correspondingly in scope. Rather, the invention includes all changes, modifications and equivalents coming within the spirit and terms of the claims appended hereto.

Features that are described and/or illustrated with respect to one embodiment may be used in the same way or in a similar way in one or more other embodiments and/or in combination with or instead of the features of the other embodiments.

It should be emphasized that the term “comprise/comprising” when used in this specification is taken to specify the presence of stated features, integers, steps or components but does not preclude the presence or addition of one or more other features, integers, steps, components or groups thereof.

### BRIEF DESCRIPTION OF THE DRAWINGS

Many aspects of the invention can be better understood with reference to the following drawings. The components in the drawings are not necessarily to scale, emphasis instead being placed upon clearly illustrating the principles of the present invention. Likewise, elements and features depicted in one drawing may be combined with elements and features depicted in additional drawings. Moreover, in the drawings, like reference numerals designate corresponding parts throughout the several views. Also, parts designated by primed reference numerals may be similar in form and/or function to parts designated by the same unprimed reference numeral.

FIGS. 1A and 1B are perspective views of electronic equipment, e.g., a mobile phone, having soft keys with holographic symbols;

FIGS. 2A-2E are schematic illustrations of a key having a hologram and different respective holographic symbols shown;

FIG. 2F is a schematic illustration of a key having a hologram and different respective holographic symbol shown with the symbol appearing in spaced-apart relation to the key;

FIG. 3 is a schematic block diagram of a control module of the electronic equipment;

FIG. 4 is a schematic illustration of a key with a hologram;

FIG. 5 is a schematic illustration of another embodiment of key with a hologram using light directors to illuminate the hologram;

FIG. 6 is a schematic block diagram of a circuit useful in the electronic equipment, e.g., mobile phone;

FIG. 7 is a schematic block diagram of exemplary logic useful in the electronic equipment with holographic symbols on soft keys; and

FIGS. 8 and 9 are plan and perspective views, respectively, of a personal digital assistant type of electronic equipment and an electronic game, each including keys with holographic symbols.

### DETAILED DESCRIPTION OF EMBODIMENTS

The term electronic equipment includes portable radio communication equipment. The term portable radio communication equipment, which hereinafter is referred to as a mobile radio terminal, includes equipment such as mobile telephones, communicators, i.e., electronic organizers, hand held computers, personal digital assistants (PDAs), smart phones or the like. The term electronic equipment also includes electronic games and other devices in which a display and a navigation device are employed during use. The term electronic equipment also includes electronic organizers, hand held computers, personal digital assistants (PDAs), games and other devices with or without telephone or similar type of communication capability.

An example of the present invention is described herein in the context of a mobile terminal in the form of a mobile telephone, but it should be understood that the mobile terminal of the present invention is not so limited and may find utility in other applications. For example, the term mobile terminal as used here may include a Personal Communications System (PCS) terminal that may combine a mobile telephone with data processing, facsimile and data communications capabilities; a Personal Digital Assistant (PDA) that can include a radiotelephone, pager, Internet/intranet access, Web browser, organizer, calendar and/or a global positioning system (GPS) receiver; a conventional laptop and/or palmtop receiver or other computer system that includes a receiver for generating different levels of sound. Mobile terminals may also be referred to as pervasive computing devices, electronic gaming, etc. In one embodiment of the present invention, the invention may be implemented on a computer system having a memory circuit for storage of data, a receiver which acts to generate different levels of sound, and a control circuit that is configured to control the flow of data between the memory and receiver. An example of the invention also is described in the context of a game, hand held computer, PDA, etc., that may or not have telephone type communication capability.

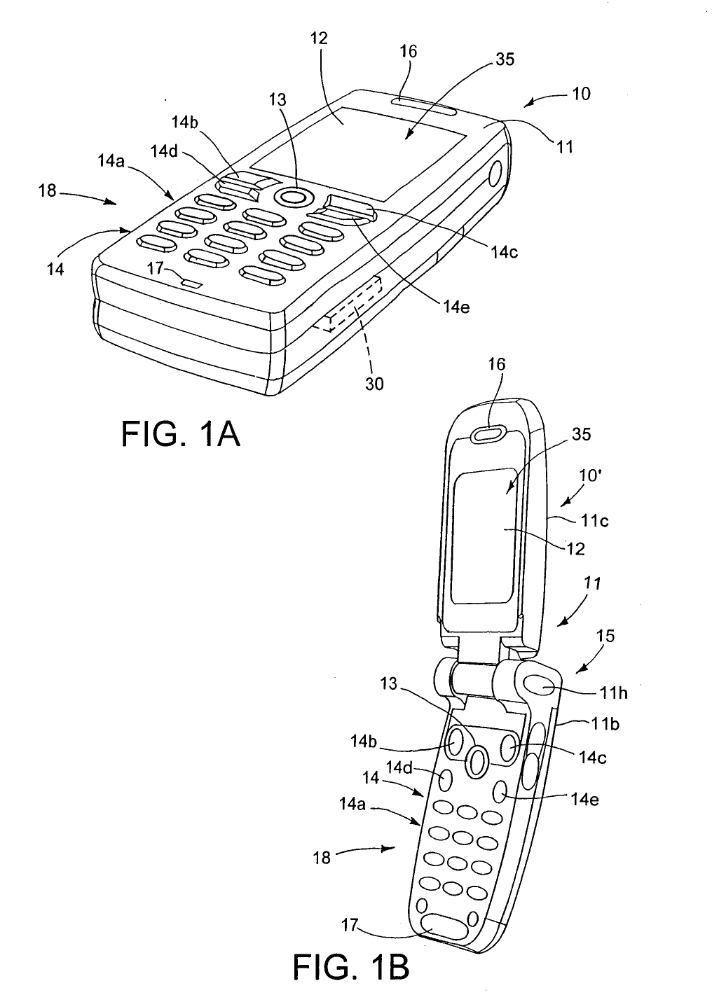

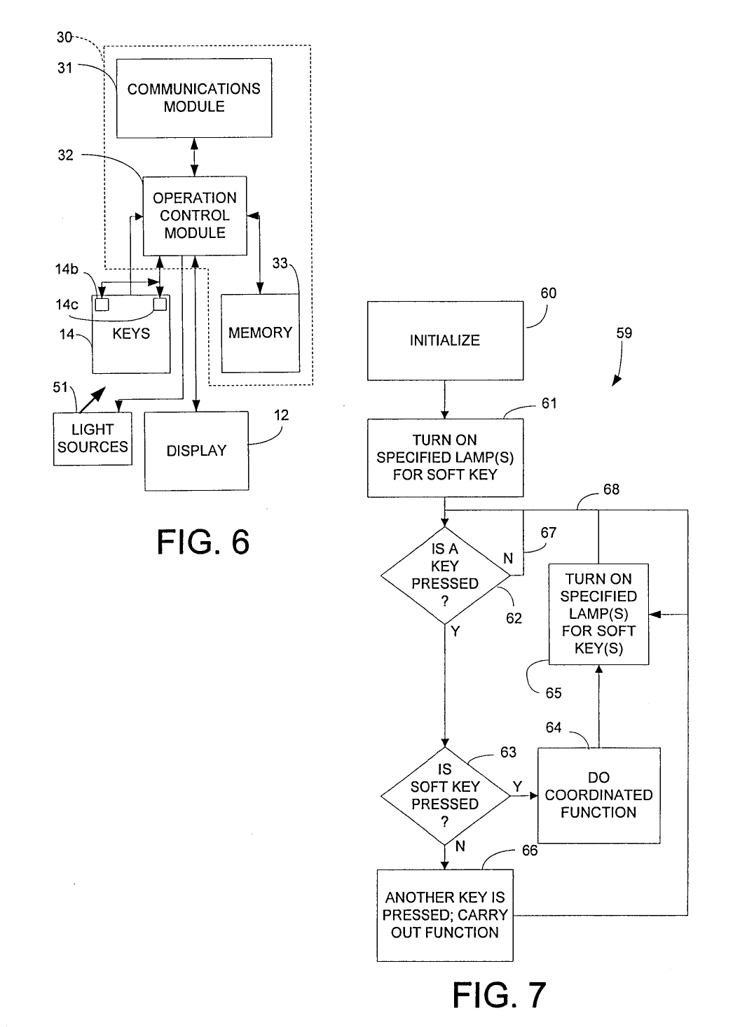

Referring to FIGS. 1A and 1B electronic equipment 10, 10′ is illustrated. In FIGS. 1A and 1B and in several of the other drawing figures the electronic equipment 10, 10′ is referred to as a mobile phone. However, as was mentioned above, the electronic equipment may be other than a mobile phone, such as, for example, any of the various devices mentioned above as electronic equipment as well as other devices that currently exist or may come into existence in the future. Thus, the mobile phone illustrated and described herein is an example of electronic equipment. Also, as is illustrated schematically in FIG. 6 a personal digital assistant (PDA) device is shown as another example of electronic equipment.

As is seen in FIGS. 1A and 1B, the mobile phone 10, 10′ includes housing 11, display 12, navigation device 13, keys 14, speaker 16, and microphone 17. The keys 14 include dialing keypad keys 14a, sometimes referred to dialing keys, keypad, or the like. The dialing keys 14a may be arranged in the conventional manner used in push button telephones, as is illustrated, but it will also be appreciated that the dialing keys may be arranged in another manner, one example of which is a QWERTY style keyboard with some of the keys being designated as alphabet letters and some of the keys being designated as number keys, and wherein some of the keys may be used both as alphabet keys, as number keys and/or as other symbol or function keys. The keys 14 also include two soft keys 14b, 14c sometimes referred to as function keys. The soft keys Although two soft keys are illustrated, it will be appreciated that there may be fewer or more soft keys, for example, soft keys 14d, 14e. The navigation device 13 may include a rocker switch, a push button switch, joy stick, track ball, and/or other mechanism to provide for navigating a cursor or the like on the display 12 and/or selecting or activating a given function that is highlighted or somehow designated on the display 12. For convenience the navigation device 13 and keys 14 may be referred to collectively or individually as an input module 18 for the mobile phone 10. The display 12 may be a touch sensitive display that provides detectable signals when touched or pressed, and, accordingly, the display, too, may be considered a part of the input module.

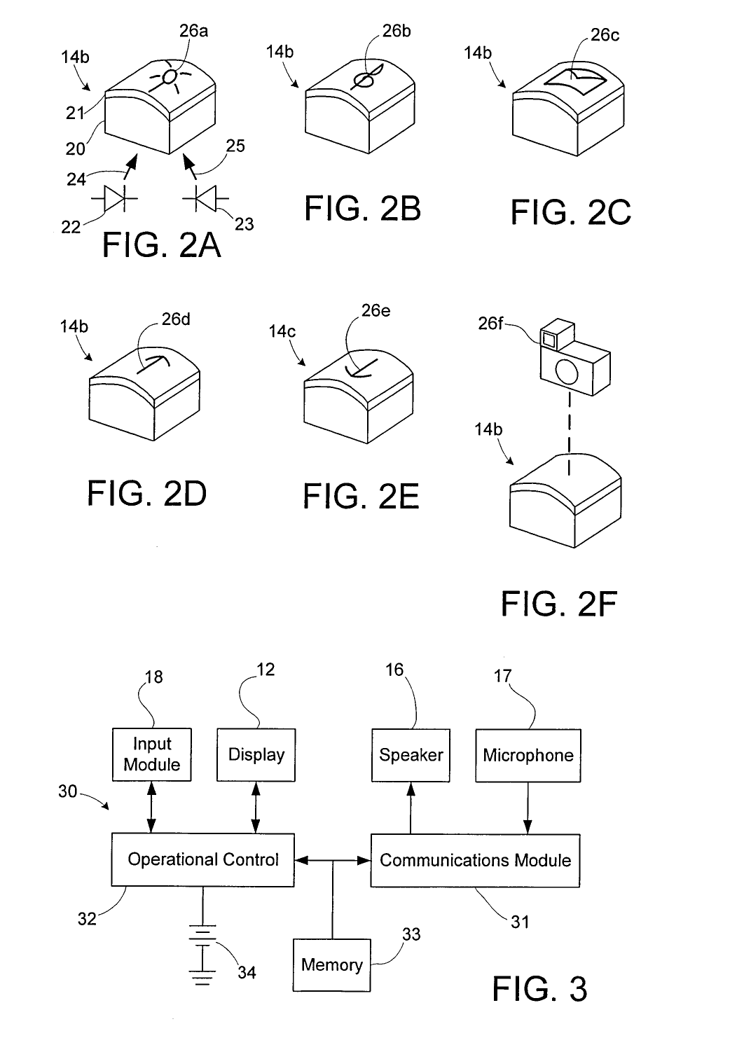

One or more of the soft keys 14b, 14c, 14d, 14e, which are described in greater detail below, has the ability to change the symbol, icon, word, image, etc. that is on the soft key to display information. The terms symbol, icon, word, image, etc., may be used equivalently and interchangeably herein to represent some type of indicia presented by a soft key. Such indicia represents information that is displayed by the key to represent the function or action of the mobile phone that would be carried out upon pressing the soft key. For example, with reference to FIG. 2A, the soft key 14b has a base 20 and has a hologram 21 associated with the base. The base may be transparent to light and the hologram may be mounted on the base, within the base, on top of the base, etc. to provide different respective images in response to illumination that is incident on the hologram.

Briefly referring to FIG. 1B, the housing 11 of the mobile phone 10 has both a base portion 11b in which keys 14 are located and a cover portion 11c in which the display 12 is located. The base and cover portions 11b, 11c are attached by a hinge 11h. In FIG. 1B the cover portion is open from the base portion so the mobile phone 10 is ready for use. In these types of mobile phones, sometimes referred to as being of the type that flips open or flips closed, the cover portion may be flipped closed about the hinge to tend to cover the keys 14. As is seen in FIG. 1B, the soft keys 14b, 14c are relatively remotely located from the display 12, e.g., being separated from the display by the hinge 11h. Other soft keys 14d, 14e of the mobile phone 10 of FIG. 1B are even more remote from the display 12. Also, as is seen in FIG. 1A, the soft keys 14d, 14e of the mobile phone 10 are not directly adjacent the display 12 and also are more remote from the display than are the soft keys 14b, 14c.

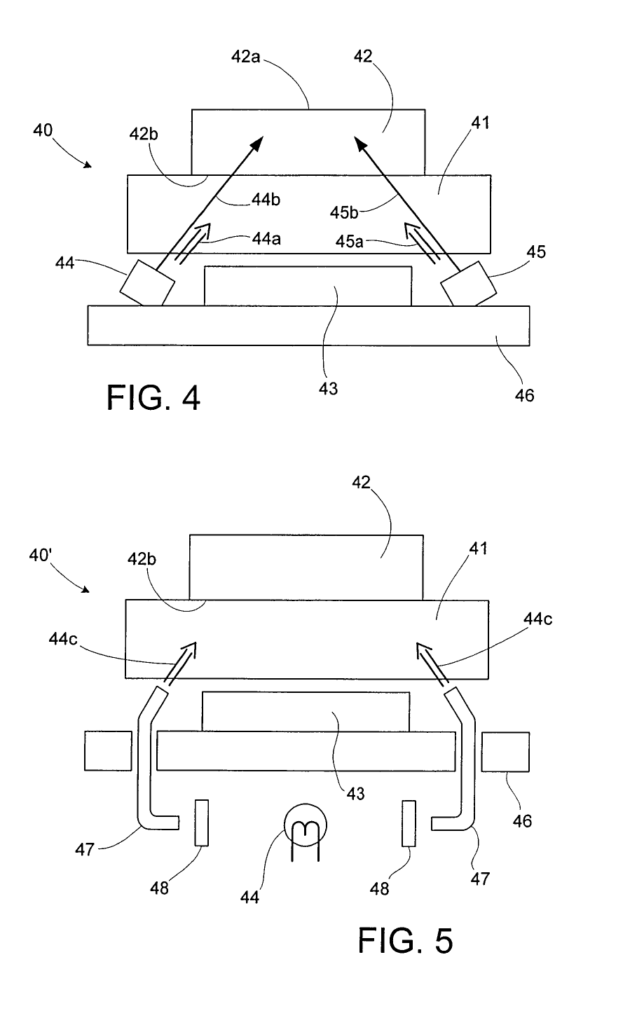

Referring to FIGS. 2A through 2F, and FIG. 4, examples of a soft key schematically are illustrated showing several different holographic symbols shown or displayed on the respective soft keys. The soft key includes a body 20 and a hologram 21. Holograms are known. Methods of making holograms so that they contain a number of different images that can be displayed, respectively, depending on the manner in which the hologram is illuminated also are known. Thus, as an example, in FIG. 2A two exemplary light sources 22, 23 are illustrated schematically to illuminate the hologram 21 using light shown as provided along light paths 24, 25 from different respective directions relative to the hologram, as also will be described in greater detail below with respect to FIG. 4.

A hologram embodies a phenomenon that provides the ability to show an image when exposed to light from a specific direction, e.g., illuminated by incident light from a given direction. A hologram may present a two dimensional image that is at the hologram or may in a sense float in space away from the physical hologram; and a hologram may provide a three dimensional image that appears in space. A hologram may provide both two dimensional images and three dimensional images. The holograms can be in different colors.

As is shown in FIGS. 2A through 2F, the hologram 21 may provide a number of different images based on the characteristics of the light illuminating the hologram, e.g., the direction of the illumination, the wavelength of the illumination, or some other characteristic. Exemplary symbols shown in FIGS. 2A through 2F include the following:

FIG. 2A shows an antenna symbol 26a representing sending and/or receiving signals. As is described further below, when the antenna symbol is shown on the soft key 14b, pressing of that key may initiate a telephone call or may answer an incoming telephone call.

FIG. 2B shows a music staff symbol 26b, which may indicate to a user that upon pressing the soft key 14b while such music symbol is shown, music would be played by the mobile phone 10 or some other music function may be carried out.

FIG. 2C shows an envelope symbol 26c, which typically represents an email function, and pressing such symbol may initiate such function, e.g., to send, to receive, to read, and/or to write email.

FIGS. 2D and 2E show soft keys 14b, 14c with arrows 26d, 26e pointing, respectively, up and down, e.g., to indicate a scrolling up or down for menu functions shown on the display 12, or the increasing or decreasing of a value shown on the display 12, etc.

FIG. 2F shows a camera symbol 26f to represent that upon pressing the soft key 14b, for example, a camera function, e.g., to take a photograph or video or to display a photograph or video, would be carried out by the mobile phone 10.

An interesting characteristic of holograms is that images formed by the hologram may be in the plane or at the hologram, or the images may be formed such that they appear floating in space. Whether the images are formed at the hologram or in space may depend on the manner in which the hologram is created and/or the manner in which the hologram is illuminated, e.g., by a single light source, by several light sources simultaneously, direction of illumination, etc., as is known. In FIGS. 2A-2E the symbols 26a-26e are shown at the hologram or in the plane of the hologram; those symbols are exemplary indicia, and they may be, for example, two dimensional images that appear either at the plane of the hologram or elsewhere, e.g., floating above the hologram. In FIG. 2F the symbol 26f is a three dimensional image that is shown floating in space above the plane of the hologram 21 of soft key 14b.

In FIGS. 1A and 3 schematically illustrated in the mobile phone 10 is a control module 30, which controls operation of the mobile phone to carry out the few or many functions of the mobile phone such as, for example, to make and to receive telephone calls and to transmit and to receive voice data, to carry out email functions, text messaging functions, and the like, to provide internet connection and associated data transmitting and receiving functions, to carry out music, video, photographic, image, and like functions, etc. The control module 30 is representative of the control and operating circuitry for the electronic equipment 10; and it will be appreciated that many control modules are known and may be used in the invention. For example, an appropriate control module may be selected for use and set up and programmed for use in the mobile phone 10 according to the functions and features to be employed in the mobile phone, such as, for example, functions and features mentioned herein and others, too. For example, referring to FIG. 3, the control module 30 may include a communications module 31 to carry out communications to and from other electronic equipment, cellular telephone towers, satellites, etc. The control module 30 also may include an operational control 32, which may control the various functions of the electronic equipment 10, including functions carried out by the communications module 31, and the various other functions mentioned herein, such as camera functions, video functions, music functions, computation functions, and other functions that currently are provided in electronic equipment of the type described herein and functions that may come into existence in the future for use in electronic equipment. The control module 30 may include a memory 33 to store programs and data for use in carrying out functions of the mobile phone 10 by the communications module 31 and the operational control 32. A power supply 34, e.g., battery, solar cell, connection to a power line or other source, etc., provides power for the control module 30 and for other parts of the mobile phone 10, as is conventional.

The control module 30 may operate and/or respond to the display 12, speaker 16 and microphone 17 in a manner the same as or similar to such operations and/or responses in conventional mobile phones. The control module 30 responds to inputs from the input module 18, e.g., in response to a user pressing one or more of the keys 14, in response to operation of the navigation device 13 by the user, and, if the electronic equipment 10 has a touch responsive screen 35 (FIGS. 1A, 1B) of the display 12, then the control module may respond to signals received from the screen, such as, pressing or tapping an area of the screen, writing on the screen, etc.

The control module 30 may control operation of the soft key 14b by determining the characteristic of illumination that is incident on the hologram 21, e.g., from light sources 22, 23, to cause the hologram to present different respective images or symbols. For example, the symbol shown at the soft key 14b is coordinated by the control module 30 with regard to a function to be carried out by the mobile phone 10, e.g., under control of the control module 30, upon pressing or otherwise activating, operating or providing an input to the soft key 14b. Thus, for example, if the mobile phone 10 is ready to play music, the control module 30 may cause the hologram 21 at the soft key 14b to show a music staff symbol 26b of FIG. 2B; and a user of the mobile phone would understand that upon pressing the soft key while such symbol is shown, music would be played by the mobile phone or that some other music function would be set up to occur under control of the control module 30, etc.

The above description of soft key 14b control of or determining of the symbols provided by the hologram 21 thereof, and input signals to the control module 30 upon operating the soft key 14b also may apply to the other soft keys, e.g., soft keys 14c, 14d and 14e, and/or to other keys associated with the mobile phone 10 or other electronic equipment. For example, the control module 30 may operate both soft keys 14b, 14c so that one shows the up arrow 26d of FIG. 2D and the other shows the down arrow 26e of FIG. 2E so that upon pressing soft key 14b, a scroll up or increased value function is carried out, and by pressing the other soft key 14c, a scroll down or decrease value function is carried out by the control module 30. As another example, on the soft key 14b the antenna symbol 26a of FIG. 2A and the soft key 14c an end symbol or the word “end” may be shown, respectively; and these may represent that upon pressing the soft key 14b, a telephone call is initiated or answered, and by pressing the soft key 14c, the telephone call is terminated. These are only several examples of coordination of two soft keys 14b, 14c with the control module 30; it will be appreciated that there may be many others. As another example, the antenna symbol may be shown on the soft key 14b to indicate that upon pressing that key a telephone call would be initiated (made) or answered; and after the key 14b had been pressed, the label (e.g., symbol, word, icon, etc.) on that key may be changed by the control module 30 to a word, symbol or icon, e.g., the word “end” or a letter “X” over the antenna symbol, etc., to indicate that upon pressing the key the call would be terminated. It will be appreciated that other coordinated functions, e.g., coordinated between the image shown by the key and the function to be carried out by the electronic equipment upon pressing the key, also may be provided the mobile phone 10. Furthermore, although the mobile phone 10 is described with respect to the two soft keys 14b, 14c, the various soft key types of functions and the coordination of showing respective symbols on keys and responding to activating or operating of such keys in coordination by and with the control module 30 also may be carried out for more than two soft keys, e.g., also by soft keys 14d, 14e by other keys of the mobile phone 10, by the navigation device 13, etc., as will be appreciated by those having ordinary skills in the art.

Still further, it will be appreciated that coordination may be provided between the image shown on a soft key and an image shown on a display, whereby, for example, a given function may be shown on the display, e.g., in proximity to a given soft key, and then different functions may be carried out upon pressing the soft key as different respective information is shown on the soft key. Examples may be showing on the display in proximity to the soft key or someplace else on the display a function, such as the word “telephone;” and the different information shown on the coordinated soft key may be an arrow facing up or out designating “make an outgoing phone call,” an arrow facing in the opposite direction designating “receive an incoming phone call,” and a letter “X” indicating “terminate the current phone call.” These are examples; many other uses also may be carried out in accordance with the invention as will be appreciated.

Turning to FIG. 4, an enlarged schematic elevation view of an exemplary soft key 40, is illustrated. The soft key 40 is exemplary of the soft keys 14b, 14c, 14d, 14e, which are described above and also is exemplary of other keys and operable or activatable devices of electronic equipment, such as, the mobile phone 10, a PDA, or other electronic equipment, that include changeable information or indicia as is described in further detail below.

The key 40 as shown is in the form of an assembly that includes a push button 41 (shown as base 20 in FIG. 2A, for example), a hologram 42 (shown as hologram 21 in FIG. 2A, for example), a switch 43, and light sources 44, 45 (shown as 22 and 23 in FIG. 2A, for example). The key 40 is mounted on, above, or otherwise with respect to a printed circuit board 46, or the soft key 40 may be in another housing or support that is provided to support the parts of the key. The hologram 42 may be, for example, a holographic film having one or more images stored therein or forming part thereof, as is conventional for holograms. As was mentioned above, in response to illumination of the hologram 42, an image is provided at the hologram, e.g., appearing within the body of the hologram 42 or at the surface 42a thereof, or the image may be provided so as to appear as though it is floating in space, e.g., as was described above with respect to FIG. 2F. Usually image information is stored in the hologram or is formed in the hologram as an interference pattern, and upon illumination of the interference pattern an image is produced or created, as is known. The light sources 44, 45 provide light 44a, 45a along light paths 44b, 45b, respectively, to illuminate the hologram 42 from different directions, as is shown schematically in FIG. 4. For example, if only one of the light sources 44, 45 were illuminating the hologram 42, the hologram would provide a given image, e.g., one of the symbols shown in FIGS. 2A-2F, and if the hologram were illuminated by only the other light source, then the hologram may provide a different image. A third image may be presented when the hologram is illuminated by light from both light sources 44, 45, the latter image possibly being a combination of the first two mentioned images.

In the illustration of FIG. 4, two light sources 44, 45, which provide light to the hologram 42 from different respective directions, are shown. However, it will be appreciated that the key 40 may include only one light source illuminating the hologram. In such instance the hologram may present only a single image or if the light source is off, a different image or no image may be presented. In another embodiment there may be more than two light sources, each of which illuminates the hologram 42 from a different respective direction, and in such embodiment it may be possible for the hologram to present more than two images, e.g., a separate image for each light source and/or a separate image for light from a combination of those light sources, etc.

The word hologram may be used to mean an image that is formed by a hologram; it may be used to mean a medium that causes a light interference pattern to occur to form an image; it may be used to mean a material, e.g., a film or other substrate or the like, having such medium; and it may have other usual meanings appropriate to the field of holography.

Two holograms may be placed in 180 degrees opposite relation relative to each other on or in a button 41. The 180 degrees relationship represents the respective directions of incident light on the respective holograms that would cause the given hologram to present a viewable intended image. As is shown in FIG. 4, illumination of the two holograms by incident light from one light source would lead to forming and presenting for viewing one image; and illumination of the holograms by incident light from the other light source, e.g., from a different direction than the light from the first light source, would lead to forming and presenting for viewing a second image. Similarly, three holograms may be placed in 120 degrees relation to each other and three respective light sources would be used, four holograms may be placed in 90 degrees relation to each other and four respective light sources would be used, etc. The number of holograms and light sources or incident light directions may depend on ghosting effects that may occur and degrade the viewable images to an undesired or unusable extent or so as to be indistinguishable. As is described elsewhere herein, the different holograms of a single key 14b, for example, may contain indicia, such as words or symbols representing play, camera, envelope, pause, call, end, etc.

In the illustration of FIGS. 2A and 4, a separate light source, e.g., light emitting diodes (LEDs), is used to illuminate each hologram of a key to cause respective indicia, e.g., words, symbols, or the like, to be presented in association with that key. Operation of the light sources may be controlled by software that is run by the control module 30, for example, to present the respective images in coordination with what application currently is running in the mobile phone 10 or other electronic equipment.

As is seen schematically in FIG. 5, in another embodiment of key 40′ light from one light source may be directed to the hologram 42 via different light paths or directions. One or more light directors, e.g., reflectors, lenses, light conducting members 47, such as fiber optic devices, etc., may be used for this purpose. A shutter 48 or other optical switch, light blocking device, etc., under control of the control module 30 may be used to allow light 44c to pass along a given path to the hologram 42 or to be blocked from the hologram, e.g., as is illustrated in the drawing.

The hologram 42 may be responsive to the wavelength of the illuminating light. For example, the hologram may present one image in response to light of one wavelength that is provided in a given direction, and the hologram may present a different image in response to light of a different color that is provided in such same given direction.

In an embodiment the hologram 42 may present an images of different colors or color combinations based on the color of incident light on the hologram and/or the direction of incident illumination on the hologram.

In the embodiment illustrated in FIGS. 4 and 5, the hologram 42 is of the type that transmits light to form or to present an image. Accordingly, the light sources 44, 45, illuminate the hologram 42 from the surface 42b, and the image is presented within the holographic film that forms the hologram 42 or at the surface 42a of the holographic film. Alternatively, image may appear floating in space above or away from the surface 42a of the hologram. (It will be appreciated that reference to direction herein is for the purpose of facilitating the description but is not necessarily a limitation on the described invention. Alternatively, the hologram 42 may be illuminated by light from above the surface 42a, and in such instance the hologram may present an image that is reflected toward or otherwise presented to be viewed by a user of the electronic equipment that includes the key 40.

In the embodiment illustrated in FIG. 4 the key 40 is positioned on, mounted with respect to, etc., a support 46. The support 46 may be a printed circuit board having a number of electrical conductors thereon, therein, and/or therethrough. The switch 43 may be a dome switch that operates in response to pressing of the button 41 against the dome switch to complete a circuit path for conductors on the printed circuit board, for example. The switch 43 may be another type of switch, as may be desired. The button 41 with the hologram 42 thereon is space apart above the dome switch 43 by a carrier or holder (not shown). The carrier or holder may include a resilient member, such as a spring, diaphragm, or some other device to space the button 41 and hologram 42 away from the switch 43 but aligned therewith so that upon pressing the key e.g., pressing against the surface 42a of the hologram or otherwise pressing button 41, the button presses against the switch 43 to operate the switch, e.g., to activate a connection between a pair of conductors or several pairs of conductors, etc., associated with the printed circuit board 46. Also, as is seen in FIG. 4, the light sources 44, 45 are mounted on the printed circuit board 46 and are aligned or positioned in such a way as to direct light 44a, 45a toward the hologram 42 along with respective light paths 44b, 45b. The button 41 may be optically transparent at least with respect to the wavelengths or color of light 44a, 45a to allow that light to illuminate the hologram 42. Suitable space is provided for the light sources 44, 45 (and others if used) so that such light sources may be mounted on the printed circuit board or otherwise positioned with respect to it in an orientation to direct light to the hologram 42.

It will be appreciated that other arrangements for light sources 44, 45 to illuminate the hologram 42 also may be used. For example, the button 41 may not be optically transparent but include light paths, e.g., openings through the button, to allow light from the light sources to illuminate the hologram 42. In another embodiment the light sources 44, 45 may be spaced away from the button 41, e.g., not directly between the button and the printed circuit board 46; for example, relative to the illustration in FIG. 4, the light sources may be moved laterally left and right, respectively, so that they still provide light through the button 41 to illuminate the hologram 42, on the one hand, but are not in the travel path of movement between the button 41 and switch 43.

The term hologram refers to a device that is able to present different respective images in response to characteristic of the illuminating light, e.g., direction of illumination, wavelength of the illuminating light, etc. The hologram 42 may be a film, e.g., plastic, polymer, etc., having a developed emulsion that represents the interference pattern. The hologram may be stamped into a structure, e.g., a polymer or other material. In these cases or others, the hologram 42 may be attached to the button 41 by an adhesive. Alternatively, the hologram may be printed on a surface of the button 41. As another alternative, the hologram may be within the button, e.g., partly or entirely encapsulated within the material of which the button is formed or sandwiched between parts of the button. Other arrangements for the hologram and button or other actuatable device of the key 40 may be used. Although the button 41 is shown as a solid and may be substantially inflexible, the button 41 alternatively may be a membrane or other relatively flexible material and/or resilient material; and in such case the key 40 may be a membrane type switch that includes a hologram 42 and a switch 43, e.g., as described herein.

FIG. 6 illustrates a schematic circuit diagram in block form showing interrelationship of the control module 30 of the mobile phone 10 with keys 14, light sources 51 (e.g., as are described above with respect to reference numerals 22, 23 and 44, 45, for example), and display 12. The light sources 51 represents the light sources providing light to illuminate the hologram 42.

The communications module 31 may be a conventional communications circuit, including a transmitter, a receiver, suitable amplifiers, signal encoding and/or decoding circuitry, etc., which are of conventional type useful, for example, in mobile phones. The communications module 31 also may include the capability for other communications functions, such as, for example, transmitting and receiving text messages, communicating via the internet or some other network, blue tooth communications, and/or other communications. The operation control module 32 may control the operation of the communications module 31, e.g., to provide signals indicating that the communications module should transmit a message, receive a message, carry out communications as in a telephone call, carry out blue tooth communications, etc. The operation control module 32 may include one or more processors, suitable logic circuitry, amplifiers, etc., for example, as typically may be included in a mobile phone or other electronic equipment, such as are mentioned herein and/or others. Associated with the operation control module 32 is memory 33 that may be used to store and provide computer programs and the like for the operation control module to carry out and control operation of various functions of the electronic equipment. The memory 33 may also store telephone numbers and other data, functions, information, images (e.g., .jpeg, .tiff, .pdg or other images), video, etc. The operation control module may access the memory 33 to retrieve data, instructions, and/or to store data, instructions, etc. in the memory.

The operation control module 32 is coupled to the display 12 to cause various images to be shown on the display. The images may include a list of telephone numbers, a list of functions, menus, images, etc. If the display 12 is of the touch screen type, then signals from the display may be communicated back to the operation control module 32 to provide respective inputs thereto, as is conventional in some electronic equipment, such as, for example, mobile phones, PDAs, etc. Functions designated by the menu items shown on the display 12 may be selected by touching the menu items if the display is a touch screen type. Alternatively, such menu items may be selected by operation of the navigation device 13 (FIGS. 1A, 1B), pressing a soft key 14b, 14c, or by some other means. The menu items shown on the display 12 may be scrolled using the navigation device 13 or using soft keys 14b, 14c, for example.

The keys 14 and the light sources 51 are coupled to the operation control module 32. Pressing or otherwise activating a key 14, e.g., to dial a telephone number, to send the telephone number to initiate a telephone call, to answer a telephone call, and to terminate a telephone call may be carried out by pressing respective dialing keys 14a (FIGS. 1A, 1B) and/or by pressing respective soft keys 14b, 14c. The operation control module 32 also controls operation of the light sources 51. Interaction between the operation control module 32, soft keys 14b, 14c, and light sources 51 is coordinated according to programming of the operation control module, such as firm ware, programming in the memory 33, etc. For example, if the mobile phone 10 is in a mode of operation to initiate or to answer a telephone call, the operation control module 32 may cause elimination of one or more light sources associated with each of the soft keys 14b, 14c to cause the soft key 14b to show a symbol representing answering a phone call or initiating a phone call and to show a symbol on the soft key 14c representing ending or terminating a phone call. If the mobile phone 10 is to be used to carry out functions pertaining to sending, receiving, responding to, writing, or erasing a text message, the operation control module may operate respective light sources 51 to illuminate respective soft keys 14b, 14c (and perhaps other soft keys) so that the soft keys present symbols representing those functions in the event the respective key were pressed or otherwise activated. Additionally, while a given symbol is shown on a soft key 14b, 14c, for example, the pressing or activating of that key provides a signal to the operation control module 32 so that such module carries out the intended function, operation, etc. It will be appreciated that although several exemplary functions are described with regard to the block diagram of FIG. 6 and the other illustrations of the electronic equipment 10 described herein, there are other operations or functions that may be carried out using the above-described method using the electronic equipment as will be apparent to those who have ordinary skill in the art.

Briefly referring to FIG. 7, a flow chart of logic or steps that may be carried out in the mobile phone is illustrated. The steps illustrated and described below may be carried out using appropriate computer program software that may be prepared by a person who has ordinary skill in the art pertaining to mobile phones and/or computer programming as will be appreciated. The illustrated steps are exemplary and it will be appreciated that other logic or steps to carry out methods for operating the mobile phone 10 in accordance with the present invention to provide different respective graphics, symbols and the like on the respective soft keys may be used. The steps illustrated in FIG. 7 may be carried out using the control module 30 of FIG. 6 and other circuitry and components of the mobile phone 10, for example.

At block 60 the control module 30 would be initialized. Initialization may set up the mobile phone 10 to send and to receive telephone calls and to terminate telephone calls that are in process. The initialization process also may set up other functions, such as music playing functions, video display or video photographing functions, digital image display or photographing functions, music playing functions, data entry functions, etc. At step 61 one or more of the light sources 51, may be turned on to cause respective symbols to be presented by the holograms associated with respective soft keys or the like to convey information to the user indicating what would happen, e.g., what function would be carried out, if a soft key were pressed. At step 62 an inquiry is made whether any key 14 has been pressed. If not, then a loop line is followed until a key has been pressed. If a key has been pressed, e.g., as sensed by the operation control module 32 receiving an input from one of the keys 14, then at block 63 an inquiry is made whether the key that had been pressed is a soft key. If the key had been a soft key, then at block 64 one or more coordinated functions would be carried out by the control module 30, the coordination being based on which soft key had been pressed and which symbol had been shown that soft key when it was pressed, as that symbol would represent a given function that is coordinated with such symbol to be carried out, such as the functions described above or other functions. At step 65 the appropriate light source 51 may be turned on or off to ready the soft key(s) for subsequent pressing to carry out subsequent functions, for example. The image (or lack of an image) on a soft key may indicate that the soft key already had been pressed or is being pressed. If at block 63 a soft key had not been pressed, then another key had been pressed, such as, for example, one of the dialing keys 14a, and as a result a given function may be carried out, as is illustrated at step 66. Such function may be the providing of a number for use as part of a telephone number that is to be dialed or is being dialed, may be an alphabet or number character that is to be part of a text message and, accordingly, is stored in a memory or otherwise is transmitted as part of the text message, may be the asterisk or pound symbol typically found on a dialing key pad to cause respective functions either in the mobile phone 10 itself or in a device that receives those characters, etc. Further, if the key 14 that had been pressed is a send or terminate key, which is other than a soft key, then in addition to providing the appropriate signal to the control module 30 from the key, the control module may operate the light sources 51 to change the symbol(s) shown on the soft keys 14b, 14c and may set the operation control module 32 properly to decode or to understand the response to be provided upon pressing one of the soft keys 14b, 14c, etc.

The method of diagram 59 of FIG. 7 may continue to be carried out as the mobile phone 10 continues to be used, as is represented by several loop lines, e.g., 67, 68. Also, similar operation may be carried out for other soft keys, navigation device 13, and switches 14, etc., that use changeable indicia, such as the holograms 42 and variable illumination of the holograms, as are described above, for example.

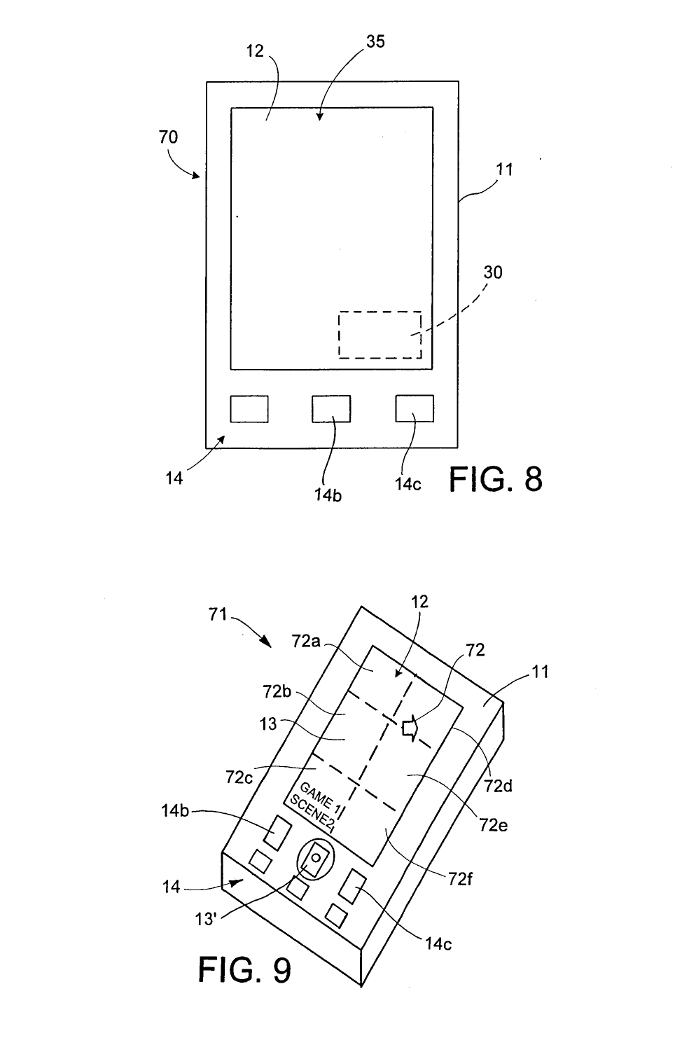

Briefly referring to FIG. 8, an example of electronic equipment in the form of a PDA 70 is illustrated. The PDA 70 may have various components similar to the mobile phone 10 and is another example of electronic equipment that includes keys 14 (only several of which are illustrated, but there may be more or fewer) some of which may be soft keys 14b, 14c, for example, on which different symbols can be presented while the control module 30 is operable to carry out respective functions represented by such symbols. In FIG. 6 various parts that are the same or similar to those illustrated in the drawings at FIGS. 1-5 are represented by the same reference numbers used for the mobile phone 10 described above.

Another example of electronic equipment is an electronic game 71 shown in FIG. 9. The game 71 may be a handheld game or a table mounted (or other surface positionable) game. The game 71 includes a navigation device 13′, such as a joy stick or track ball, and several soft keys 14b, 14c. The navigation device may be used to move a cursor 72 to point to images at respective locations 72a-72f on the display 12, and the keys 14, including the soft keys 14a, 14b, may be pressed or otherwise operated to carry out game functions.

1. Electronic equipment, comprising
a communications module, and
an input module, and wherein
the input module comprises
at least one manually operable key and
an optical device having a number of distinguishable indicia associated with said key and being selectable to display respective indicia based on a respective characteristic of illumination thereof.

2. The electronic equipment of claim 1, wherein the respective characteristic of illumination is direction of illumination.

3. The electronic equipment of claim 1, wherein the optical device is a hologram.

4. The electronic equipment of claim 1, wherein the respective characteristic is wavelength of light.

5. The electronic equipment of claim 1, wherein the communications module comprises a mobile phone.

6. The electronic equipment of claim 1, wherein the communications module comprises a personal digital assistant.

7. The electronic equipment of claim 1, wherein the optical device is adapted to provide images located at the optical device.

8. The electronic equipment of claim 1, wherein the optical device is adapted to provide images spaced apart from the optical device.

9. The electronic equipment of claim 1, further comprising a number of light sources respectively providing visible light to the optical device from different locations.

10. The electronic equipment of claim 1, further comprising electronic apparatus operable to control the communications module, the electronic apparatus and the input module being cooperatively related whereby the respective distinguishable indicia provided by the optical device are determined under control of the electronic apparatus.

11. Electronic equipment, comprising
operational component to carry out functions (display, computation, calculation, listing of music, telephone communications) in response to an input from an operated key,
a key adapted to provide an input to the operational component, the key including
a hologram adapted to provide respective distinguishable optical outputs (views, images, information) in response to the characteristics of incident light provided the hologram.

12. The electronic equipment of claim 11, further comprising a plurality of light paths along which light inputs are provided, respectively, to the hologram to provide different respective distinguishable optical outputs.

13. A switch for electronic equipment, comprising
an activatable element operable to provide a discernible indication of being selectively activated,
a changeable display in the activatable element and adapted to provide at least two distinguishable optical outputs in response to respective optical inputs, such outputs indicative, respectively, of anticipated effect of activating the activatable element.

14. A method for providing distinguishable optical outputs for electronic equipment, comprising providing respective light inputs to a hologram associated with an operable key to indicate the function to be carried out upon operating such key.

15. The method of claim 14, further comprising changing the characteristic of incident light on the hologram to change indicia shown by the hologram.

16. The method of claim 15, said change the characteristic comprising changing the direction of incidence.

17. The method of claim 15, said changing the characteristic comprising changing the wavelength of light.
